(19) United States
(12) Patent Application Publication
(10) Pub. No.: US 2019/0057920 A1
(43) Pub. Date: Feb. 21, 2019

(54) SEMICONDUCTOR PACKAGE AND METHOD FOR MANUFACTURING THE SAME

(71) Applicant: Advanced Semiconductor Engineering, Inc., Kaohsiung (TW)

(72) Inventors: Chia-Ling LEE, Kaohsiung (TW); Ming-Wei SUN, Kaohsiung (TW); Chin-An SU, Kaohsiung (TW); Cheng-Hua LIU, Kaohsiung (TW)

(73) Assignee: Advanced Semiconductor Engineering, Inc., Kaohsiung (TW)

(21) Appl. No.: 16/168,825

(22) Filed: Oct. 24, 2018

Related U.S. Application Data
(62) Division of application No. 14/749,471, filed on Jun. 24, 2015.

(51) Int. Cl. H01L 23/31

(52) U.S. Cl. CPC H01L 23/3128; H01L 2924/15331; H01L 2224/16227; H01L 2924/1815; H01L 2225/1023; H01L 2924/15311; H01L 2225/1058

(57) ABSTRACT

A method for manufacturing a semiconductor package includes: (a) providing a package device, the package device comprising a substrate, a package body and a plurality of connecting elements, the substrate having a first surface, the package body being disposed adjacent to the first surface of the substrate, and the connecting elements being disposed adjacent to the first surface of the substrate and encapsulated by the package body; and (b) removing a portion of the package body along one or more machining paths to expose the connecting elements, wherein each machining path has one or more first paths passing over, between, or along a side of at least two connecting elements, wherein a portion of each of the at least two connecting elements is within the package body, and another portion of each of the at least two connecting elements protrudes from a surface of the package body.

### CROSS-REFERENCE TO RELATED APPLICATION

This application is a divisional of U.S. patent application Ser. No. 14/749,471, filed on Jun. 24, 2015, the content of which is incorporated herein by reference its entirety.

### TECHNICAL FIELD

The present disclosure relates to a semiconductor package and a method for manufacturing the same. In particular, the present disclosure relates to a semiconductor package including at least two exposed connecting elements and a method for manufacturing the same.

### DESCRIPTION OF THE RELATED ART

In general, a package-on-package (POP) structure includes two or more stacked packages, such as a top package stacked on a bottom package. To form electrical connections between the top package and the bottom package, a top surface of the bottom package may have exposed pads or interconnects, to which respective interconnects or pads at a bottom surface of the top package connect. Improvements in the electrical connections of a POP structure are desirable.

### SUMMARY

An aspect of the present disclosure relates to a semiconductor package. In an embodiment, the semiconductor package includes a substrate, a package body and at least two connecting elements. The substrate has a first surface. The package body is disposed adjacent to the first surface of the substrate, and the package body defines a groove having a substantially flat bottom surface. The connecting elements are disposed adjacent to the first surface of the substrate. A portion of each of the connecting elements is within the package body, and another portion of each of the connecting elements protrudes from the substantially flat bottom surface of the groove.

Another aspect of the present disclosure relates to a semiconductor package. In an embodiment, the semiconductor package includes a substrate, a package body and one or more connecting elements. The substrate has a first surface. The package body is disposed adjacent to the first surface of the substrate, and the package body defines a groove. The connecting elements are disposed adjacent to the first surface of the substrate and are partially encapsulated by the package body. The connecting elements are positioned together within the groove and are exposed from the package body.

Another aspect of the present disclosure relates to a method for manufacturing a semiconductor package. In an embodiment, the method includes: (a) providing a package device, the package device comprising a substrate, a package body and a plurality of connecting elements, the substrate having a first surface, the package body being disposed adjacent to the first surface of the substrate, and the connecting elements being disposed adjacent to the first surface of the substrate and encapsulated by the package body; and (b) removing a portion of the package body along one or more machining paths to expose the connecting elements, wherein each machining path has one or more first paths passing over, between, or along a side of at least two connecting elements, wherein a portion of each of the at least two connecting elements is within the package body, and another portion of each of the at least two connecting elements protrudes from a surface of the package body.

### BRIEF DESCRIPTION OF THE DRAWINGS

FIG. 1 is a cross-sectional view of a semiconductor package according to an embodiment of the present disclosure.

FIG. 2 is a partially enlarged view of area ‘A’ of the semiconductor package illustrated in FIG. 1.

FIG. 3 is a partially enlarged view of area ‘B’ of the semiconductor package illustrated in FIG. 2.

FIG. 4 is a cross-sectional view taken along line 4-4 of FIG. 2 according to an embodiment of the present disclosure.

FIG. 5 is a top view of the semiconductor package illustrated in FIG. 1 according to an embodiment of the present disclosure.

FIG. 6 is a partially enlarged view of area ‘C’ of the semiconductor package illustrated in FIG. 5.

FIG. 7 is a cross-sectional view taken along line 7-7 of FIG. 6 according to an embodiment of the present disclosure.

FIG. 8 is a cross-sectional view taken along line 8-8 of FIG. 6 according to an embodiment of the present disclosure.

FIG. 9 is a top view of a semiconductor package according to another embodiment of the present disclosure.

FIG. 10 is a cross-sectional view of a semiconductor package according to another embodiment of the present disclosure.

FIG. 11 is a cross-sectional view of a POP structure according to an embodiment of the present disclosure.

FIG. 12, FIG. 13, FIG. 14, FIG. 15, FIG. 16 and FIG. 17 illustrate a method for manufacturing a semiconductor package according to an embodiment of the present disclosure.

### DETAILED DESCRIPTION

A POP structure may include a top package stacked on a bottom package, where electrical interconnects (or pads) are exposed at a top surface of the bottom package. To expose an interconnect, a laser beam may be applied (such as in a laser drilling process) to remove a portion of an encapsulant that covers the interconnect. However, this is a slow process, as the laser beam is moved through a circular path to form a hole exposing the interconnect, and one hole at a time is formed. The time spent forming the hole is thus multiplied by the number of holes that are formed, which corresponds to the number of interconnects to be exposed.

Further, a width of the laser beam may be such that, for fine-pitch devices (e.g., less than 0.27 millimeter (mm)), as the laser beam forms a hole over one interconnect, energy in the laser beam may spread over areas including interconnects already exposed, which may damage the already-exposed interconnects. Accordingly, due to poor accuracy in the positioning of the laser beam, the laser-drilled holes may be kept small to avoid such beam spread from affecting neighboring interconnects. However, small holes leave small areas of the interconnects exposed, which may result in poor bonding. Thus, a hole diameter is often too small to accept a sufficient amount of a molten interconnect (e.g., solder) as it expands during bonding to prevent overflow of the molten interconnect outside of the hole. Such overflow may extend into neighboring exposed holes, thereby creating an electrical bridge between holes.

Additionally, when the circular laser beam path is defined in part by the size of the interconnect or the size of the hole formed over the interconnect, or is defined in part by the pitch of neighboring interconnects, the path of the laser beam is specific to the package layout. In such a situation, a change in size of the interconnect or hole, or a change in the pitch between neighboring interconnects, results also in a change to the laser beam path.

A potential solution for some of the challenges described is to form a larger hole, by using a wider laser beam, or by expanding the circular path, such that the hole formed has a bottom plane with an area greater than the diameter of the interconnect. That is, the bottom plane of the hole is annular around the interconnect. However, the wider laser beam, or the expanded circular path of the laser beam, may remove excess bottom encapsulant to expose the solder mask under the bottom encapsulant, and may additionally expose traces covered by the solder mask, which in turn may result in oxidation of the traces.

An improved technique provides for more exposure of the interconnects for better electrical connection, while maintaining an integrity of a solder mask and traces under an encapsulant.

FIG. 1 is a cross-sectional view of a semiconductor package 1 according to an embodiment of the present disclosure. In one or more embodiments, the semiconductor package 1 is a bottom package of a POP structure. The semiconductor package 1 includes a substrate 10, first ball pads 12, traces 14, bump pads 16, a first solder mask 18, second ball pads 20, a second solder mask 22, a semiconductor die 24, conductive bumps 26, a package body 28, upper connecting elements 30 and lower connecting elements 32.

The substrate 10 has a first surface 101 and a second surface 102 opposite to the first surface 101. The first ball pads 12, the traces 14 and the bump pads 16 are included in a first circuit pattern disposed on a first surface 101 of the substrate 10. The traces 14 may be disposed between first ball pads 12. For example, as illustrated in the area surrounded by dotted line in FIG. 1 (labeled ‘A’), one trace 14 is routed between two adjacent first ball pads 12. In other embodiments, two or more traces 14, or no traces 14, may be routed between two adjacent first ball pads 12. The first solder mask 18 covers the first surface 101 of the substrate 10, and the first ball pads 12 and the bump pads 16 are exposed from the first solder mask 18. The second ball pads 20 are included in a second circuit pattern disposed on a second surface 102 of the substrate 10. The second solder mask 22 covers the second surface 102 of the substrate 10, and the second ball pads 20 are exposed from the second solder mask 22.

The semiconductor die 24 is disposed adjacent to the first surface 101 of the substrate 10, and is electrically connected to the first circuit pattern (e.g., including the first ball pads 12, the traces 14 and the bump pads 16) on the first surface 101 of the substrate 10. In this embodiment, the semiconductor die 24 is electrically connected to the first circuit pattern by flip chip bonding, that is, the semiconductor die 24 is connected to the bump pads 16 through the conductive bumps 26. However, in another embodiment, the semiconductor die 24 may be electrically connected to the first circuit pattern by wire bonding.

The package body 28 is disposed adjacent to the first surface 101 of the substrate 10. The material of the package body 28 is, for example, an encapsulant or a molding compound, and the package body 28 is disposed on the first solder mask 18. The package body 28 includes a groove 34 or multiple grooves 34. The groove 34 has a first inner side wall 281, a second inner side wall 282 and a bottom surface 283. The bottom surface 283 is a substantially flat surface.

The upper connecting elements 30 are disposed adjacent to the first surface 101 of the substrate 10, and the upper connecting elements 30 are positioned around a periphery of the semiconductor die 24. In this embodiment, the upper connecting elements 30 are solder balls, and are disposed on respective ones of the first ball pads 12. However, in other embodiments, the upper connecting elements 30 may be solder bumps, gold stud bumps or metal pins, and a shape of the upper connecting elements 30 may be spherical, columnar, or other shape. A portion of each of the upper connecting elements 30 is within the package body 28, and another portion of each of the upper connecting elements 30 protrudes from and is exposed from the bottom surface 283 of the groove 34, such that neighboring upper connecting elements 30 protrude from the same substantially flat surface. In other words, the upper connecting elements 30 are disposed adjacent to the first surface 101 of the substrate 30, and are partially encapsulated by the package body 28. Multiple upper connecting elements 30 may be exposed in a single groove 34.

The lower connecting elements 32 are disposed adjacent to the second surface 102 of the substrate 10. In this embodiment, the lower connecting elements 32 are solder balls, and are disposed on respective ones of the second ball pads 20.

In one or more embodiments, the groove 34 may be formed by a laser process according to a predetermined pattern as described below. The groove 34 is formed around two or more upper connecting elements 30 in the same process, therefore manufacturing throughput is increased as compared to a process in which holes are formed over a single upper connecting element 30 at a time. Further, a pitch between the upper connecting elements 30 will not impede the formation of the groove 34. For example, when the pitch between the upper connecting elements 30 is less than 0.27 mm, the groove 34 still can be formed, and one upper connecting element 30 will not be adversely impacted by excess laser beams. Thus, the use of the grooves 34, instead of individual holes over the upper connecting elements 30, can avoid damage to the upper connecting elements 30. Additionally, a pattern of the path of the laser beam does not correspond to the pitch and the size of the upper connecting elements 30; thus, even if the pitch or the size of the upper connecting elements 30 changes, the design of the pattern of the path of the laser beam can remain without change. A further benefit is that the groove 34 has a volumetric capacity sufficient to avoid overflow of solder during the bonding process, thereby avoiding solder bridges.

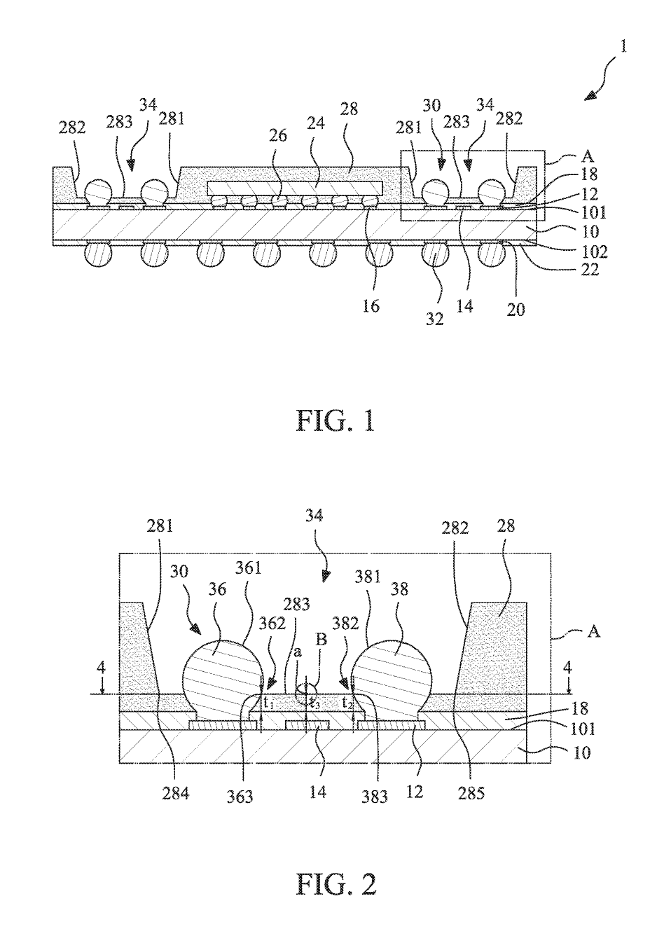

FIG. 2 is a partially enlarged view of area ‘A’ of the semiconductor package 1 illustrated in FIG. 1. The first inner side wall 281 intersects with the bottom surface 283 to form a first inner edge 284, and the second inner side wall 282 intersects with the bottom surface 283 to form a second inner edge 285. In the embodiment illustrated in FIG. 2, the upper connecting elements 30 include a first upper connecting element 36 and an adjacent second upper connecting element 38. The first upper connecting element 36 has an exposed outer surface 361, and the exposed outer surface 361 intersects with the substantially flat bottom surface 283 of the groove 34 to form a first corner 362 and a first connecting element edge 363. The second upper connecting element 38 has an exposed outer surface 381, and the exposed outer surface 381 intersects with the substantially flat bottom surface 283 of the groove 34 to form a second corner 382 and a second connecting element edge 383. The bottom surface 283 of the groove 34 extends between the first corner 362 of the first upper connecting element 36 and the second corner 382 of the second upper connecting element 38. That is, there is an empty space between the exposed outer surfaces 361, 381 of the respective two upper connecting elements 36, 38, without a bulk protrusion of the package body 28 from the substantially flat bottom surface 283 between the corners 362, 382 of the respective two upper connecting elements 36, 38.

The two adjacent corners 362, 382 and a middle point ‘a’ on the bottom surface 283 between the two adjacent corners 362, 382 are substantially at the same level. In other words, a thickness t₁ of the package body 28 corresponding to the first corner 362 is substantially equal to a thickness t₂ of the package body 28 corresponding to the second corner 382, and is also substantially equal to a thickness t₃ of the package body 28 corresponding to the middle point ‘a’. In one or more embodiments, the entire bottom surface 283 of the groove 34 is substantially parallel with the first surface 101 of the substrate 10. In one or more embodiments, the thickness t₁≈t₂≈t₃ is about 40 micrometers (μm).

In one or more embodiments, as illustrated in FIG. 2, at least one trace 14 is disposed between two first ball pads 12 corresponding to the upper connecting elements 36, 38, and the trace 14 is covered by the first solder mask 18, which in turn is covered by the package body 28. The trace 14 is not exposed, and the first solder mask 18 is not exposed, due to using a laser beam to form the groove 34 (rather than using a laser beam to form an annular area around the upper connecting elements 36, 38, which tends to apply excessive localized laser energy to the package body 28 such that the first solder mask 18, or the first solder mask 18 and the trace 14, may be exposed).

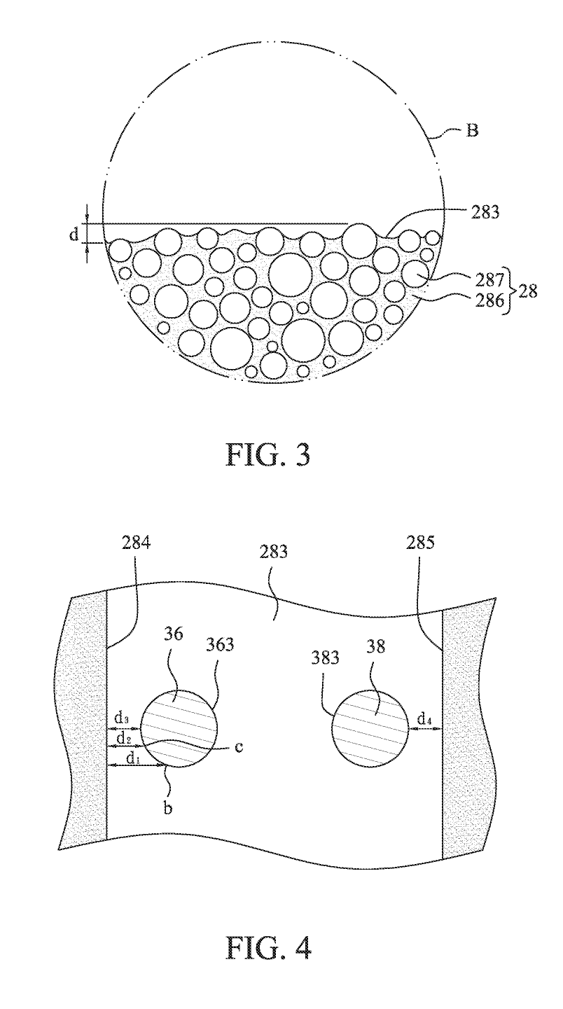

FIG. 3 is a partially enlarged view of area ‘B’ of FIG. 2, focusing on the substantially flat bottom surface 283 of the groove 34. In one or more embodiments, such as the embodiment illustrated in FIG. 3, the package body 28 is a molding compound which includes a resin 286 (e.g., an epoxy resin) and fillers 287 (e.g., silicon dioxide) distributed in the resin 286. The groove 34 is formed by a laser, thus, the fillers 287 protrude somewhat from the resin 286 by an amount depending on the type of resin used and its corresponding susceptibility to laser energy, as well as the susceptibility of the fillers 287 to the laser energy. Accordingly, a surface roughness of the substantially flat bottom surface 283 is defined by the types of resin 286 and fillers 287, as well as the size (e.g., average diameter, mean diameter or maximum diameter) of the fillers 287. In one or more embodiments, the surface roughness (Ra) of the entire bottom surface 283 is about 3 μm to about 20 μm, and a difference ‘d’ between a highest point and a lowest point of the bottom surface 283 is about 5 μm to about 10 μm.

FIG. 4 is a cross-sectional view taken along line 4-4 of FIG. 2. In the embodiment illustrated in FIG. 4, the first inner edge 284 and the second inner edge 285 are straight lines, and the first connecting element edge 363 and the second connecting element edge 383 are circular shapes that correspond to profiles of the first upper connecting element 36 and the second upper connecting element 38, respectively. A first distance d₁ is between a first position ‘b’ of the first connecting element edge 363 and the first inner edge 284, and a second distance d₂ is between a second position ‘c’ of the first connecting element edge 363 and the first inner edge 284. The first position ‘b’ is different from the second position ‘c’, and the first distance d₁ is different from the second distance d₂. In addition, a third distance d₃ is defined as a shortest distance between the first inner edge 284 and the first connecting element edge 363 nearest to the first inner edge 284, and a fourth distance d₄ is defined as a shortest distance between the second inner edge 285 and the second connecting element edge 383 nearest to the second inner edge 285. The third distance d₃ may be equal to or different from the fourth distance d₄. For example, the groove 34 may be displaced to one side or the other during the formation of the groove 34, depending on accuracy of the positioning of the laser beam, especially when shrinkage of the substrate 10 occurs. A benefit of the use of the groove 34 is that it is tolerant of such displacement, in that, even with displacement, it is possible to expose the upper connecting elements 36, 38.

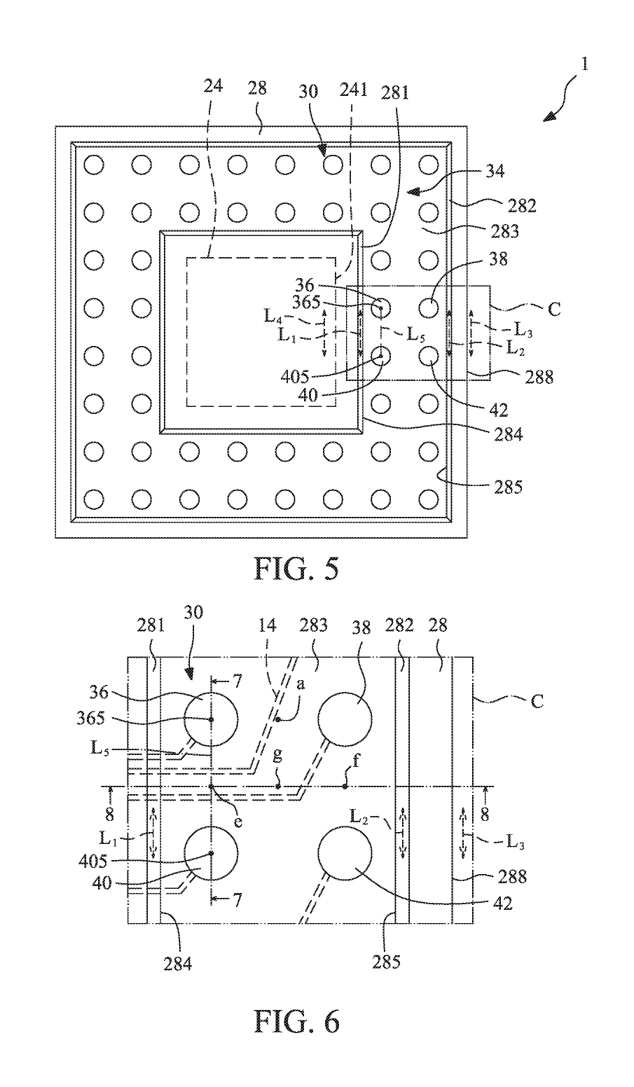

FIG. 5 is a top view of the semiconductor package 1 illustrated in FIG. 1 in one embodiment. In this embodiment, the upper connecting elements 30 are positioned around a periphery of the semiconductor die 24, and the groove 34 is a single continuous ring groove surrounding the semiconductor die 24, such that all of the upper connecting elements 30 are exposed in the single groove 34. In other embodiments, the groove 34 may include two or more concentric ring grooves 34, or may include discontinuous grooves 34.

Referring still to FIG. 5, the first inner side wall 281 of the groove 34 extends along a first longitudinal direction L₁, the second inner side wall 282 of the groove 34 extends along a second longitudinal direction L₂, and the first longitudinal direction L₁ is substantially parallel with the second longitudinal direction L₂. Therefore, the groove 34 has a substantially single width along each side of the semiconductor package 1. In addition, the package body 28 has a periphery outer surface 288 extending along a third longitudinal direction L₃, and the third longitudinal direction L₃ is substantially parallel with the first longitudinal direction L₁ or the second longitudinal direction L₂. Further, the semiconductor die 24 has a periphery outer surface 241 extending along a fourth longitudinal direction L₄, and the fourth longitudinal direction L₄ is substantially parallel with the first longitudinal direction L₁ or the second longitudinal direction L₂ The upper connecting elements 30 further include a third upper connecting element 40 and a fourth upper connecting element 42. The first upper connecting element 36, the second upper connecting element 38, the third upper connecting element 40 and the fourth upper connecting element 42 are arranged in an array. The first upper connecting element 36 has a central axis 365, and the third upper connecting element 40 has a central axis 405. An imaginary line L₅ extends between the central axis 365 and the central axis 405, and the imaginary line L₅ is substantially parallel with the first longitudinal direction L₁ of the first inner side wall 281 or the second longitudinal direction L₂ of the second inner side wall 282.

FIG. 6 is a partially enlarged view of area C of the semiconductor package 1 illustrated in FIG. 5. In this embodiment, there are traces 14 disposed between the upper connecting elements 36 and 40. A middle point ‘e’ between the first upper connecting element 36 and the third upper connecting element 40, and a middle point ‘f’ between the third upper connecting element 38 and the fourth upper connecting element 42, are located on the substantially flat bottom surface 283 of the groove 34. A middle point ‘g’ is located between the middle point ‘e’ and the middle point ‘f’, and the middle point ‘g’ is also located on the substantially flat bottom surface 283 of the groove 34.

FIG. 7 is a cross-sectional view taken along line 7-7 of FIG. 6. In this embodiment, the third upper connecting element 40 has an exposed outer surface 401, and the exposed outer surface 401 intersects with the substantially flat bottom surface 283 of the groove 34 to form a third corner 402. The bottom surface 283 of the groove 34 extends between the first corner 362 of the first upper connecting element 36 and the third corner 402 of the fourth upper connecting element 40. That is, there is an empty space between the exposed outer surfaces 361, 402 of the two upper connecting elements 36, 40, with no bulk protrusion of the package body 28 from the bottom surface 283 between the corners 362, 402. The two adjacent corners 362, 402 and the middle point ‘e’ are substantially at the same level. In other words, the thickness t₁ of the package body 28 corresponding to the first corner 362 is substantially equal to a thickness t₄ of the package body 28 corresponding to the third corner 402, and is also substantially equal to a thickness t₅ of the package body 28 corresponding to the middle point ‘e’. In addition, in the embodiment illustrated in FIG. 7, two traces 14 are disposed between two first ball pads 12.

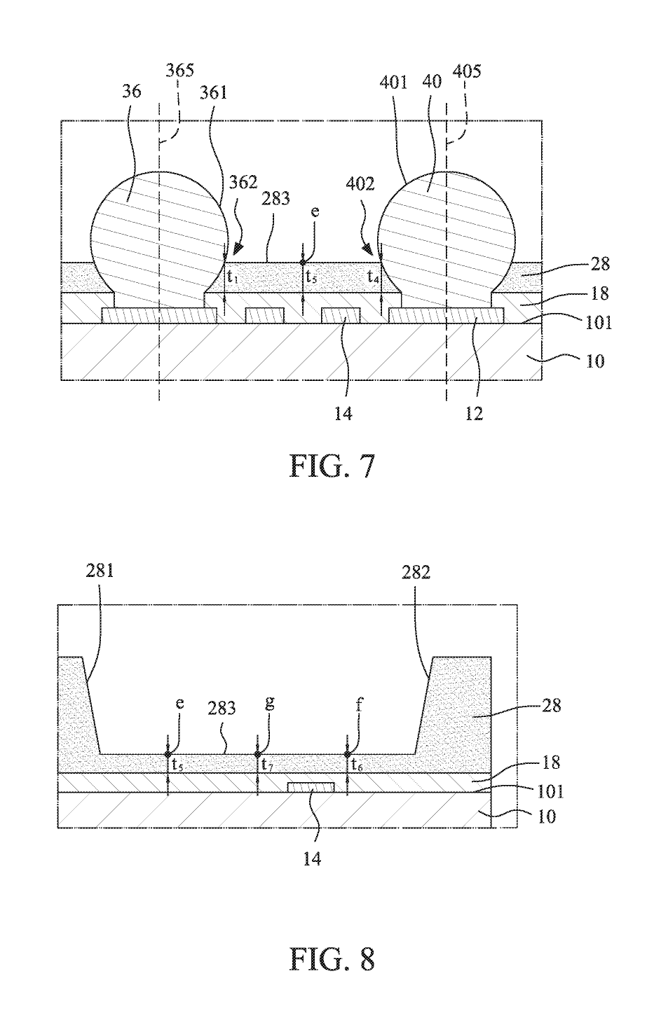

FIG. 8 is a cross-sectional view taken along line 8-8 of FIG. 6, through the middle point ‘e’ and through points ‘f’ and ‘g’, where point ‘f’ is a middle point between the upper connecting elements 38, 42, and the point ‘g’ is a middle point between the four upper connecting elements 36, 38, 40, 42. The middle points ‘e’, ‘g’ are substantially at the same level. In other words, the thickness t₅ of the package body 28 corresponding to the middle point ‘e’ is substantially equal to a thickness t₆ of the package body 28 corresponding to the middle point ‘f’, and is also substantially equal to a thickness t₇ of the package body 28 corresponding to the middle point ‘g’.

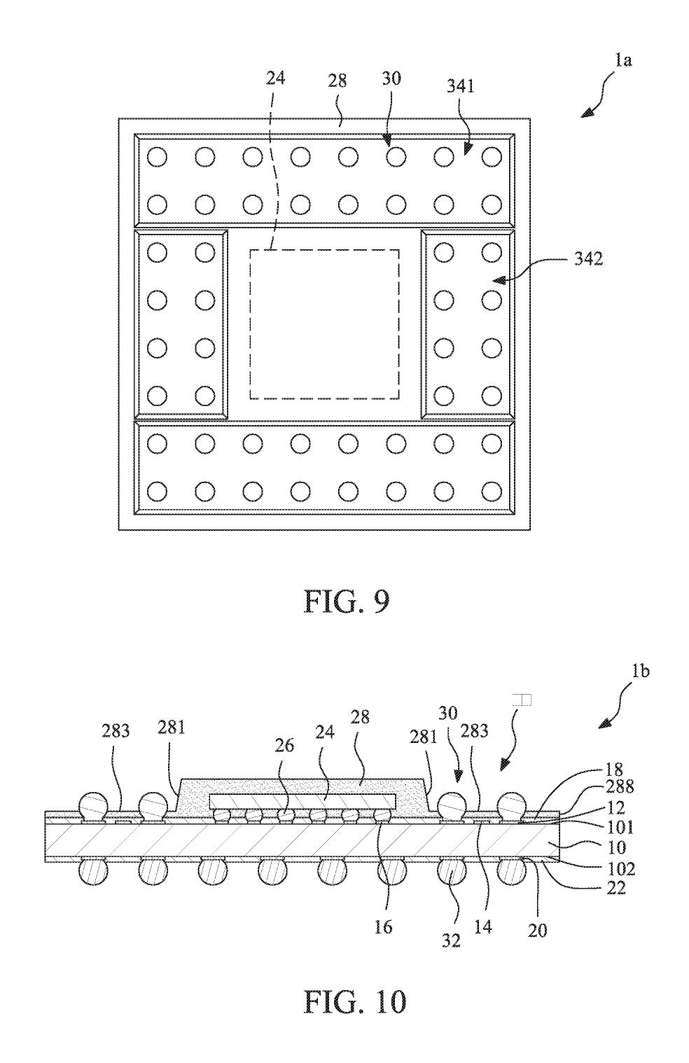

FIG. 9 is a top view of a semiconductor package 1a according to another embodiment of the present disclosure. The semiconductor package 1a of this embodiment is similar to the semiconductor package 1 illustrated in FIG. 5, except that instead of the single groove 34 of FIG. 5, the semiconductor package 1a includes four discontinuous grooves, including grooves 341, 342. The grooves (e.g., 341, 342) are separated from each other, and at least two upper connecting elements 30 protrude from a substantially flat bottom surface of each of the grooves 341, 342.

FIG. 10 is a cross-sectional view of a semiconductor package 1b according to another embodiment of the present disclosure. The semiconductor package 1b of this embodiment is similar to the semiconductor package 1 illustrated in FIG. 5, except that the substantially flat bottom surface 283 of the groove 34 extends to the periphery outer surface 288 of the package body 28.

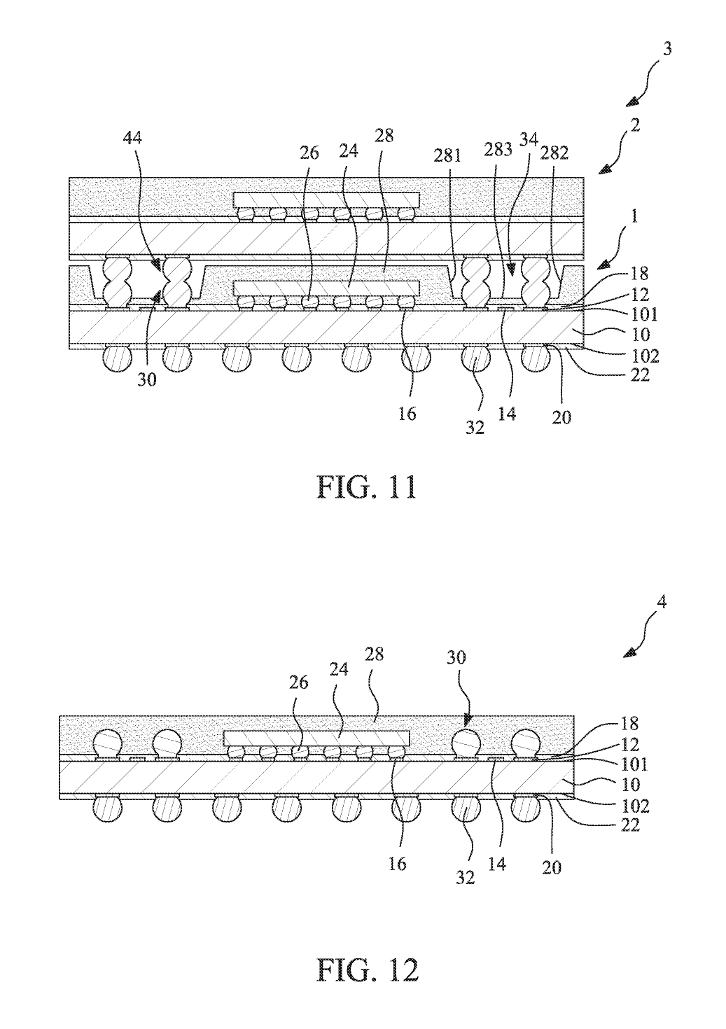

FIG. 11 is a cross-sectional view of a POP structure 3 according to an embodiment of the present disclosure. The POP structure 3 includes a bottom package 1 and a top package 2 stacked on the bottom package 1. The top package 2 includes lower connecting elements 44. The bottom package 1 is the semiconductor package 1 illustrated in FIGS. 1 to 8, and includes the substrate 10, the semiconductor die 24, the package body 28 and the upper connecting elements 30. The upper connecting elements 30 are exposed in the groove 34 of the package body 28. The lower connecting elements 44 are connected to respective ones of the upper connecting elements 30 in the groove 34, so that the top package 2 is physically connected and electrically connected to the bottom package 1. Other embodiments of a POP structure can include a bottom package corresponding to the semiconductor package 1a or 1b of FIGS. 9 to 10.

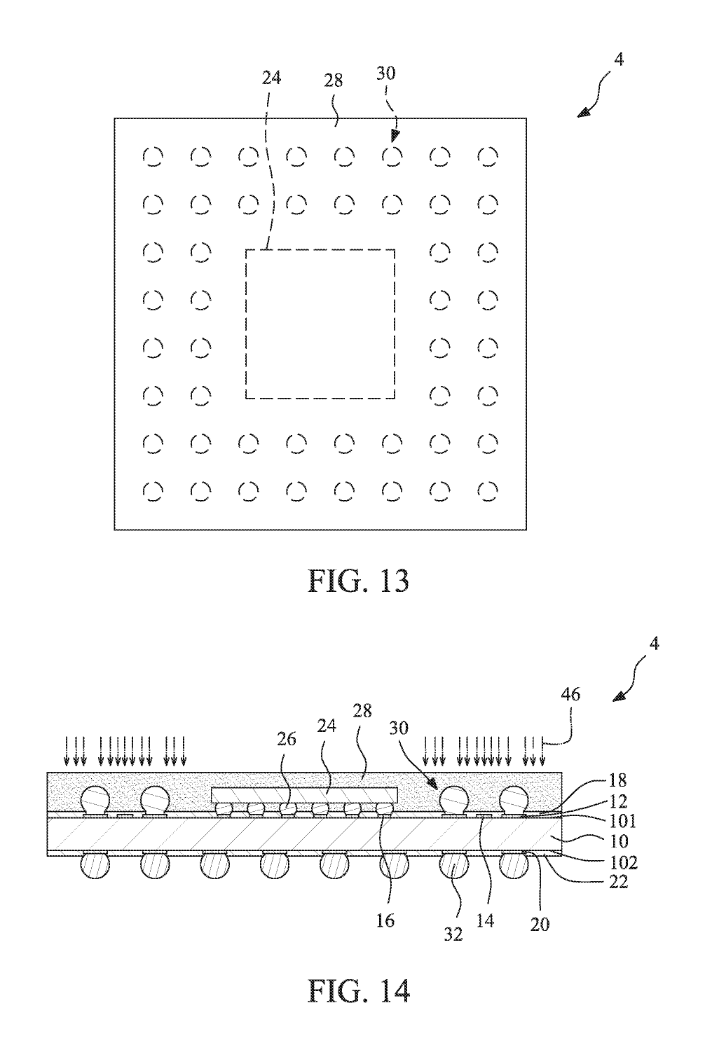

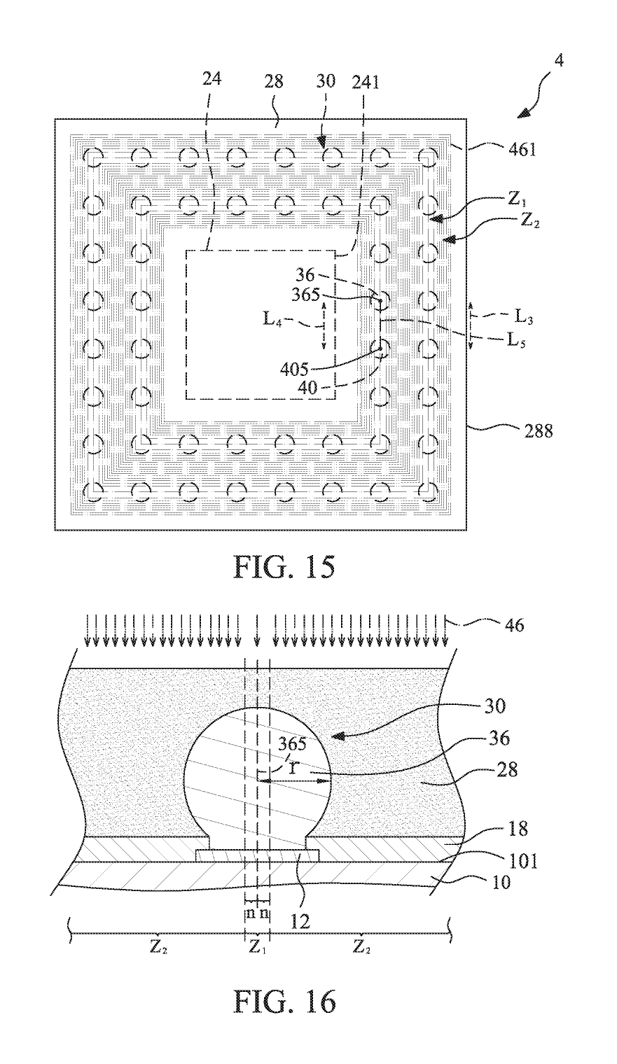

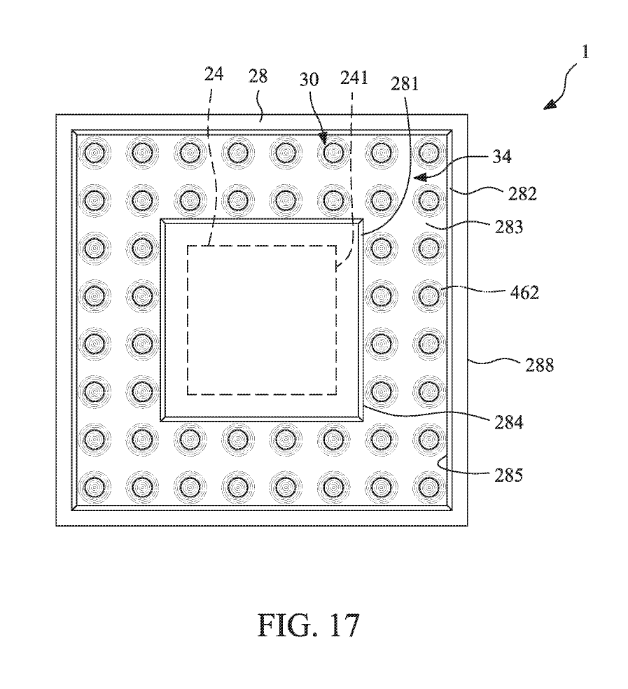

FIGS. 12-17 illustrate a method for manufacturing a semiconductor package according to an embodiment of the present disclosure. Referring to FIG. 12, a package device 4 is provided. The package device 4 includes a substrate 10, first ball pads 12, traces 14, bump pads 16, a first solder mask 18, second ball pads 20, a second solder mask 22, a semiconductor die 24, conductive bumps 26, a package body 28, upper connecting elements 30 and lower connecting elements 32. The substrate 10 has a first surface 101 and a second surface 102 opposite to the first surface 101. The first ball pads 12, the traces 14 and the bump pads 16 are disposed on the first surface 101 of the substrate 10. The first solder mask 18 covers the first surface 101 of the substrate 10, and the first ball pads 12 and the bump pads 16 are exposed from the first solder mask 18. The second ball pads 20 are disposed on the second surface 102 of the substrate 10. The second solder mask 22 covers the second surface 102 of the substrate 10, and the second ball pads 20 are exposed from the second solder mask 22. The semiconductor die 24 is disposed adjacent to the first surface 101 of the substrate 10, and is electrically connected to the first surface 101 of the substrate 10. The package body 28 is disposed adjacent to the first surface 101 of the substrate 10. In this embodiment, the package body 28 is disposed on the first solder mask 18. The upper connecting elements 30 are disposed adjacent to the first surface 101 of the substrate 10 and are disposed on respective ones of the first ball pads 12. The upper connecting elements 30 are covered/encapsulated by the package body 28. The lower connecting elements 32 are disposed adjacent to the second surface 102 of the substrate 10, and are disposed on respective ones of the second ball pads 20.

FIG. 13 is a top view of the package device 4 illustrated in FIG. 12. The semiconductor die 24 and the upper connecting elements 30 are covered/encapsulated by the package body 28, and so are shown by dotted lines.

Referring to FIG. 14, a portion of the package body 28 corresponding to the upper connecting elements 30 is removed along one or more machining paths so as to expose the upper connecting elements 30. In this embodiment, the machining paths are paths followed by one or more laser beams 46. The laser beams 46 are applied on areas above the upper connecting elements 30.

FIG. 15 is a top view of the package device 4 and the paths of the laser beam 46 illustrated in FIG. 14. In this embodiment, the machining path (the path of the laser beam 46) includes one or more paths 461 passing over, between, or along a side of two or more upper connecting elements 30 so that multiple connecting elements 30 are exposed with the same machining path, thereby increasing manufacturing throughput (e.g., units per hour (UPH)) as compared to a process that exposes single connecting elements 30 in a sequential manner. Each of the paths 461 surrounds the semiconductor die 24 so that the pattern of the machining path is approximately square concentric loops of the paths 461. In this embodiment, the upper connecting elements 30 include a first upper connecting element 36 and a third upper connecting element 40 adjacent to the first upper connecting element 36. The first upper connecting element 36 has a central axis 365, and the third upper connecting element 40 has a central axis 405 (where the central axis 365 and the central axis 405 are relative to the upper connecting elements 30 in the manner illustrated in the embodiment of FIG. 7). An imaginary line L₅ extends between the central axis 365 and the central axis 405, and where the paths 461 cross the first upper connecting element 36 and the third upper connecting element 40, the paths 461 are substantially parallel with the imaginary line L₅. Further, the package body 28 has a periphery outer surface 288 extending along a third longitudinal direction L₃, the semiconductor die 24 has a periphery outer surface 241 extending along a fourth longitudinal direction L₄, and where the paths 461 cross the first upper connecting element 36 and the third upper connecting element 40, the paths 461 are substantially parallel with the third longitudinal direction L₃ or the fourth longitudinal direction L₄.

As shown in FIG. 15, some of the paths 461 pass through a zone Z₁ over the upper connecting elements 30, and some of the paths 461 pass through a zone Z₂ without the upper connecting elements 30. A density (number per unit area) of the paths 461 passing through the zone Z₁ over the upper connecting elements 30 is lower than a density of the paths 461 passing through the zone Z₂ without the upper connecting elements 30. That is, a number of the paths 461 in a unit area of the second zone Z₂ is greater than a number of the paths 461 in a unit area of the first zone Z₁, to avoid damage to the upper connecting elements 30.

FIG. 16 is a partially enlarged view of the package device 4 as illustrated in FIG. 14, focusing on the upper connecting element 36. The first upper connecting element 36 has a central axis 365 and a radius r. The width of the first zone Z₁ is defined as the width extending from the central axis 365 to the right side and to the left side by a distance n. Thus, the width of the first zone Z₁ is 2n. In this embodiment, n is about r/6, and the width of the first zone Z₁ is about r/3. The area outside the first zone Z₁ is the second zone Z₂. In this embodiment, the density of the paths 461 within the second zone Z₂ is about four times the density of the path 461 within the first zone Z₁.

Referring to FIG. 17, after the paths 461 of the laser beam 46 are applied for a period of time, the groove 34 is formed in the package body 28 so as to obtain the semiconductor package 1 illustrated in FIGS. 1 to 8. The groove 34 has the first inner side wall 281, the second inner side wall 282 and the bottom surface 283. The bottom surface 283 is a substantially flat surface. At least two upper connecting elements 30 protrude from and are exposed from the same substantially flat surface (i.e., the bottom surface 283) of the groove 34. An additional laser beam (the laser beam 46 or other type of laser beam) may be further applied on the upper connecting elements 30 according to one or more second paths 462. In this embodiment, one second path 462 corresponds to one upper connecting element 30 so that the additional laser beam is used to remove a residue of the package body 28 on the upper connecting elements 30. That is, the additional laser beam focuses on an individual upper connecting element 30 to remove residual package body 28 rather than to form a groove or hole. In this embodiment, the pattern of the second paths 462 is a spiral path or circular concentric loops. Other embodiments of a manufacturing method can be used to form the semiconductor package 1a or 1b of FIGS. 9 to 10.

As used herein, the terms “substantially” and “about” are used to describe and account for small variations. When used in conjunction with an event or circumstance, the terms can refer to instances in which the event or circumstance occurs precisely as well as instances in which the event or circumstance occurs to a close approximation. For example, the terms can refer to less than or equal to ±10%, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

For example, the term “substantially flat” can refer to a surface roughness (Ra) of no greater than about 20 micrometers, no greater than about 15 micrometers, or no greater than about 10 micrometers, such as about 3 μm to about 20 μm, or where a difference between a highest point and a lowest point of the surface is no greater than about 20 micrometers, no greater than about 15 micrometers, or no greater than about 10 micrometers, such as about 5 μm to about 10 μm. Similarly, the term “substantially at the same level” can refer to a difference of no greater than about 20 micrometers, no greater than about 15 micrometers, or no greater than about 10 micrometers, such as about 5 μm to about 10 μm.

For another example, the term “substantially equal” in the context of thickness values can refer to a difference no greater than about 20 micrometers, no greater than about 15 micrometers, or no greater than about 10 micrometers, such as about 5 μm to about 10 μm. For another example, the term “substantially parallel” with respect to two edges or surfaces can refer to lying along a line or along a plane, with an angular displacement between the two edges or surfaces being less than or equal to 10°, such as less than or equal to 5°, less than or equal to 3°, less than or equal to 2°, or less than or equal to 1°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A method for manufacturing a semiconductor package, comprising:
(a) providing a package device, the package device comprising a substrate, a package body and a plurality of connecting elements, the substrate having a first surface, the package body being disposed adjacent to the first surface of the substrate, and the connecting elements being disposed adjacent to the first surface of the substrate and encapsulated by the package body; and
(b) removing a portion of the package body along one or more machining paths to expose the connecting elements, wherein each machining path has one or more first paths passing over, between, or along a side of at least two connecting elements, wherein a portion of each of the at least two connecting elements is within the package body, and another portion of each of the at least two connecting elements protrudes from a surface of the package body.

2. The method according to claim 1, wherein in (b), the machining paths are paths followed by one or more laser beams.

3. The method according to claim 1, wherein in (b), the multiple connecting elements are exposed with the same machining path.

4. The method according to claim 1, wherein in (b), each of the first paths surrounds a semiconductor die so that a pattern of the machining path is approximately square concentric loops of the first paths.

5. The method according to claim 4, wherein the semiconductor die has a peripheral outer surface extending along a longitudinal direction, and the first paths are substantially parallel with the longitudinal direction.

6. The method according to claim 1, wherein in (b), the connecting elements include a first connecting element and a second upper connecting element adjacent to the first connecting element, the first connecting element has a central axis, and the second connecting element has a central axis, an imaginary line extends between the central axis of the first connecting element and the central axis of the second connecting element, the first paths cross the first connecting element and the second connecting element, and the first paths are substantially parallel with the imaginary line.

7. The method according to claim 1, wherein in (b), at least some of the first paths pass through a zone over the connecting elements, and at least some other of the first paths pass through a zone without being over the connecting elements.

8. The method according to claim 1, wherein in (b), the connecting elements include a first connecting element, the first connecting element has a central axis and a radius r, a width of a first zone Z₁ is defined as a width extending from the central axis to a right side and to a left side by a distance n, the width of the first zone Z₁ is 2n, n is about r/6, the width of the first zone Z₁ is about r/3, an area outside the first zone Z₁ is a second zone Z₂, a density of the first paths within the second zone Z₂ is about four times a density of the first paths within the first zone Z₁.

9. The method according to claim 1, wherein in (b), a density of the first paths passing between or along a side of the at least two connecting elements is greater than a density of the first paths passing over the connecting elements.

10. The method according to claim 1, wherein in (b), a groove is formed in the package body so as to expose the connecting elements, the groove has a first inner side wall, a second inner side wall and a bottom surface, the bottom surface is a substantially flat surface.

11. The method according to claim 10, wherein at least two connecting elements protrude from and are exposed from the same substantially flat surface of the groove.

12. The method according to claim 1, wherein in (b), at least one machining path has one or more second paths corresponding to at least one connecting element, to remove a residue of the package body on the connecting element.

13. The method according to claim 12, wherein in (b), an additional laser beam is further applied on the connecting elements according to the second paths.

14. The method according to claim 13, wherein the additional laser beam focuses on an individual connecting element to remove a residual package body.

15. The method according to claim 14, wherein a pattern of the second paths is a spiral path or circular concentric loops.
